(19) United States
(12) Patent Application Publication
(10) Pub. No.: US 2021/0362379 A1
(43) Pub. Date: Nov. 25, 2021

(54) RESIN MOLDING DEVICE

(71) Applicant: APIC YAMADA CORPORATION, Nagano (JP)

(72) Inventors: Masahiko Fujisawa, Nagano (JP); Hirofumi Saito, Nagano (JP)

(73) Assignee: APIC YAMADA CORPORATION, Nagano (JP)

(21) Appl. No.: 17/320,213

(22) Filed: May 13, 2021

(30) Foreign Application Priority Data
May 22, 2020 (JP) 2020-089939

(51) Int. Cl. B29C 43/18; B29C 43/58

(52) U.S. Cl. CPC B29C 43/18; B29L 2031/34; B29C 2043/189; B29C 43/58

(57) ABSTRACT

A resin molding device that is easy to handle until a thin and large-size workpiece is delivered to a loader, and can supply the workpiece to a mold frame while preventing the workpiece from losing its flatness and being damaged is provided.

A resin molding device includes a workpiece transfer part (2) that reciprocates between a first position and a second position and transfers a workpiece (W), and in the workpiece transfer part (2), a holder plate (5) larger than an external form of the workpiece and having a thick plate thickness is mounted on a transfer part main body (2a), and the workpiece (W) that is positioned with respect to and overlaps the holder plate (5) based on the external form is transferred.

### CROSS-REFERENCE TO RELATED APPLICATION

This application claims the priority benefit of Japan Application No. 2020-089939, filed on May 22, 2020. The entirety of the above-mentioned patent application is hereby incorporated by reference herein and made a part of this specification.

### BACKGROUND

### Technical Field

The present invention relates to a resin molding device in which a workpiece in which an electronic component (a semiconductor chip, etc.) is mounted on a thin plate type carrier and a mold resin are loaded into a mold frame and compressed and molded.

### Description of Related Art

When a workpiece in which an electronic component (a semiconductor chip, etc.) is mounted on a thin plate type carrier with a thickness of about 0.4 mm and a size of about 500 mm (for example, a glass plate, etc.) is compressed and molded using a thermosetting resin, since the carrier has very low rigidity, adverse effects such as loss of flatness of the workpiece due to deflection during conveyance and uneven distribution of the resin supplied onto the carrier are assumed. Therefore, for example, a configuration in which the workpiece is conveyed with another support member is assumed.

For example, a technology in which a substrate is disposed on a dedicated tray including an opening for preheating in order to seal a thick electronic unit with a resin and is conveyed and preheated before resin molding has been proposed (refer to Patent Document 1: Japanese Patent Laid-Open No. 2011-116085).

### PATENT DOCUMENTS

[Patent Document 1] Japanese Patent Laid-Open No. 2011-116085

However, when the above thin and large-size workpiece is supplied to the mold frame, since the carrier has very low rigidity, there are problems of difficulties in handling such as loss of flatness of the workpiece due to deflection during conveyance when conveyed in a tray having an opening and uneven distribution of a resin (a granular resin, a liquid resin, etc.) supplied onto the carrier. In addition, when measurement is performed in order to supply an appropriate amount of a mold resin used for compression mold onto the carrier, it may be difficult to perform supply of the resin and measurement while providing support in a flat state.

The present invention provides a resin molding device that can stably and flatly convey a thin and large-size workpiece in a predetermined alignment state.

### SUMMARY

The present invention has the following configuration. A resin molding device in which a workpiece in which an electronic component is mounted on a thin plate type carrier and a mold resin are loaded into a mold frame and compressed and molded, includes a workpiece transfer part that reciprocates between a first position and a second position and transfers the workpiece, wherein, in the workpiece transfer part, a holder plate larger than an external form of the workpiece and having a thick plate thickness is mounted on a transfer part main body, and wherein the workpiece that is positioned with respect to and overlaps the holder plate based on the external form is transferred.

When the workpiece is received by the workpiece transfer part that reciprocates between a first position and a second position, since the workpiece that is positioned with respect to and overlaps the holder plate larger than the external form of the workpiece and having a thick plate thickness based on the external form on the transfer part main body is transferred, the thin and large-size workpiece can be stably and flatly conveyed in a predetermined alignment state.

In order to process the workpiece in a processing part provided on the way when the workpiece is transferred between a first position and a second position in the workpiece transfer part, the workpiece that is mounted on the holder plate may be transferred to the processing part for each holder plate. Thereby, each holder plate can be transferred to the processing part for processing (for example, resin supply, etc.) without losing the flatness of the workpiece.

In the holder plate, preferably, a positioning part that is aligned and mounted in a measuring unit provided in a resin supply part is provided. Thereby, when the workpiece is transferred together with the holder plate from the workpiece transfer part to the resin supply part by the pick and place mechanism, the workpiece is not bent, deformed or damaged, and the positioning part of the holder plate is aligned with the measuring unit in an overlapping manner, and thus the workpiece can be transferred without positional displacement, and since the workpiece is not easily deformed, an appropriate amount of the resin can be supplied onto the workpiece without uneven distribution.

The workpiece transfer part may reciprocate between a reception position at which the workpiece is received in the previous process and a delivery position at which the workpiece is delivered to a loader into which the workpiece is loaded in the mold frame. Thereby, while the workpiece is received by the workpiece transfer part at a reception position in the previous process and is transferred to a delivery position at which the workpiece is delivered to the loader, the workpiece is prevented from being deformed and handling becomes easier.

A concave part may be formed in the holder plate, the electronic component mounted on the workpiece may be housed in the concave part and the workpiece may be supported in an overlapping manner. In this case, the electronic component may be supported in the concave part with an auxiliary plate provided at least in the central part of the concave part, the depth of the concave part may be equal to the height of the electronic component mounted on the workpiece, and the entire mounted component may be supported by the concave part. Thereby, the flatness of the workpiece can be maintained and the workpiece can be conveyed to the lower mold cavity type mold frame.

For the holder plate, a metal plate may be used. Thereby, even if the workpiece W has low rigidity, it can be conveyed stably and flatly without being deflected.

### BRIEF DESCRIPTION OF THE DRAWINGS

FIG. 1 is a layout configuration diagram showing an example of a resin molding device.

FIG. 2 is a layout configuration diagram of a workpiece transfer part and a resin supply part.

FIG. 3 is an explanatory diagram showing a configuration example of a resin supply stage.

FIG. 4A to FIG. 4C show a perspective view, a plan view, and a front view of a workpiece transfer part and a holder plate.

FIG. 5A to FIG. 5C are a cross-sectional explanatory diagrams showing an aspect of a holder plate.

### DESCRIPTION OF THE EMBODIMENTS

According to the present invention, it is possible to provide a resin molding device that is easy to handle until a thin and large-size workpiece is delivered to a loader, and can supply the workpiece to a mold frame while preventing the workpiece from losing its flatness and being damaged.

(Overall Configuration)

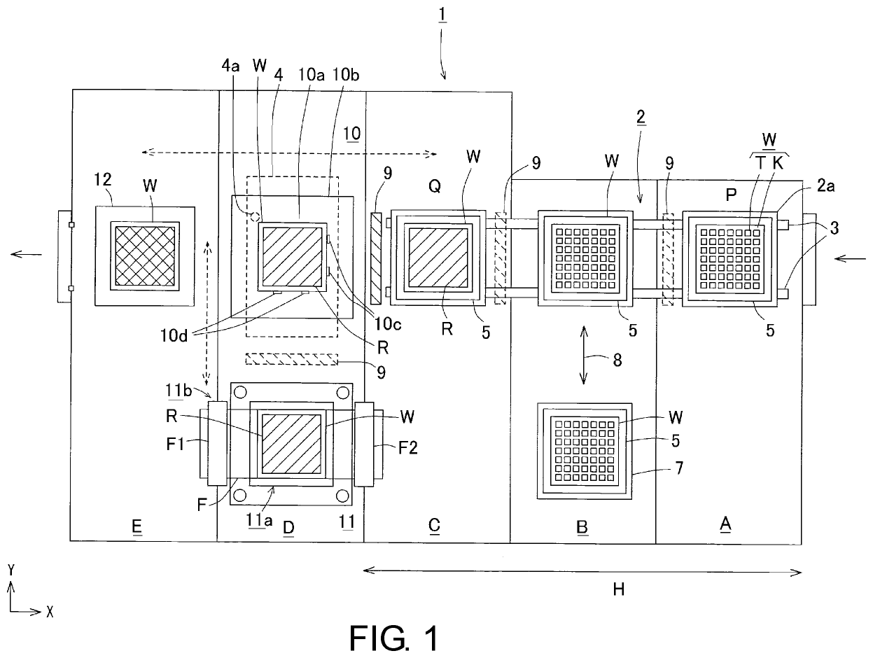

Hereinafter, referring to the drawings, an embodiment of the present invention will be described with reference to FIG. 1. FIG. 1 is a layout configuration diagram of a resin molding device according to an embodiment of the present invention. As the resin molding device, an upper mold cavity type compression molding device 1 is exemplified, and a workpiece W will be described assuming that an electronic component T such as a semiconductor chip is mounted on a thin-plate carrier K (for example, a copper plate, a glass plate, etc.) with a thickness of about 0.2 mm to 3 mm and a size of about 400 mm to 700 mm. As the following device configuration, a device configuration in which a plurality of functional units (units) are linked will be exemplified, but respective functional units may be integrally provided in the device main body. In addition, in all drawings for explaining each embodiment, members having the same function are denoted with the same reference numerals and redundant descriptions thereof may be omitted.

In the compression molding device 1, a workpiece supply unit A, a resin supply unit B, a workpiece delivery unit C, a press unit D, and a cooling unit E are each linked in series. A resin supply stage 7 and a press part 11, which will be described below, are disposed on the front side of the device in consideration of operability and maintenance, and a workpiece transfer part 2 is disposed on the back side of the device.

In the workpiece transfer part 2, a transfer part main body 2a reciprocates between a reception position P and a delivery position Q along a rail part 3 provided between the workpiece supply unit A, the resin supply unit B, and the workpiece delivery unit C (refer to the solid arrow H in FIG. 1). In the workpiece supply unit A, the reception position P at which the workpiece W is received from the previous process is provided. In addition, in the workpiece delivery unit C, the delivery position Q at which the workpiece W is delivered to a loader 4 is provided. The transfer part main body 2a is linked to a conveyor belt by, for example, a conveyor device, and reciprocates. In addition, a holder plate 5 having a sizer larger than and having a thickness thicker (for example, about 10 mm) than the external form of the workpiece is mounted on the transfer part main body 2a. The workpiece W that is positioned with respect to and overlaps the holder plate 5 is stably and flatly transferred in a predetermined alignment state by the workpiece transfer part 2.

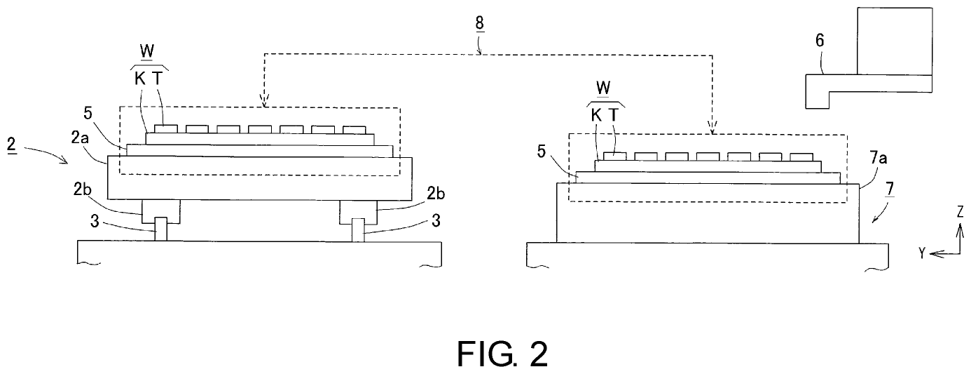

In the resin supply unit B, a dispenser 6 and the resin supply stage 7 through which a granular resin or a liquid resin is supplied is provided. As shown in FIG. 2, the resin supply stage 7 is replaced with a pick and place mechanism 8 that can move in the Y-Z direction while the workpiece W is disposed on the holder plate 5, and a resin R is supplied onto the workpiece W by the dispenser 6. The dispenser 6 is provided so that it is scannable on the workpiece W in the X-Y direction. In the resin supply stage 7, an electronic balance 7a (measuring unit) is provided, and an appropriate amount of a resin is measured and supplied onto the workpiece W.

In the workpiece delivery unit C, the delivery position Q at which the workpiece W onto which the resin R is supplied is delivered to the loader 4 is provided. In addition, a unit (not shown) that delivers the workpiece W from a delivery position Q to the loader 4 is provided, and the workpiece W is delivered from the holder plate 5 to the loader 4. In the loader 4, an annular pressing member (frame: not shown) and a plurality of chuck claws are provided, and the loader 4 holds the outer circumferential part of the workpiece W in a vertical insertion manner. The workpiece W held at the delivery position Q by the loader 4 while only its outer circumference is clamped to a preheating part 10 (a preheating stage 10b) of the press unit D is conveyed. In this manner, the compression molding device 1 that is a molding device has a configuration in which, according to applications, the workpiece transfer part 2 that positions and overlaps the workpiece W with respect to the holder plate 5 and makes it stable and flat in a predetermined alignment state and the loader 4 that performs conveyance when only the outer circumference of the workpiece W is clamped are combined.

In the workpiece delivery unit C, a cleaner device 9 that removes a resin powder and dust such as foreign substances (contaminants) attached to the back surface of the workpiece W is provided. In addition, the cleaner device 9 is cleaned when the back side of the workpiece W onto which a resin held by the loader 4 is supplied is conveyed to the press unit D (preheating part). The cleaner device 9 in which a cleaner head part is divided into a plurality of parts in the width direction is provided so that the height position can be changed. The cleaner device 9 is provided so that it is vertically movable by a servo mechanism (not shown), and can be cleaned by adjusting the height position of the cleaner head part in order to avoid deflection of the workpiece W held by the loader 4 and interference with a chuck (not shown) of the loader hand.

In the press unit D, the preheating part 10 and the press part 11 are provided. In the preheating part 10, a preheater 10a is provided. The preheater 10a preheats the workpiece W onto which a resin is supplied that is disposed on the preheating stage 10b to about 100° C.

The press part 11 includes a mold frame 11a having an upper mold and a lower mold. In the present example, the resin and the workpiece W are disposed on the lower mold, the cavity is formed in the upper mold, the mold is closed and heating is performed to, for example, about 130° C. to 150° C., for compression molding. The lower mold is movable and the upper mold is fixed, but the lower mold may be fixed and the upper mold may be movable, or both molds may be movable. Here, the mold frame 11a is mold-opened and closed by a known mold opening and closing mechanism (not shown). For example, the mold opening and closing mechanism includes a pair of platens, a plurality of link mechanisms (tie bars and pillars) on which the pair of platens are erected, a drive source (for example, an electric motor) for moving (elevating) the platens, a drive transmission mechanism (for example, a toggle link), and the like (the drive mechanism is not shown).

In the mold frame 11a, a release film F is sucked and held on the surface of an upper mold clamp including the upper mold cavity. A film conveyance mechanism 11b is provided on the upper mold. For the release film F, an elongated continuous film material having excellent heat resistance, ease of peeling, flexibility, and extensibility is used, and for example, polytetrafluoroethylene (PTFE), polytetrafluoroethylene polymer (ETFE), PET, FEP, fluorine-impregnated glass cloth, polypropylene, polyvinylidene chloride, and the like are preferably used. The release film F is conveyed through the surface of the upper mold clamp from a feed roller F1 to a winding roller F2 in a winding manner. Here, instead of the elongated film, a strip-shaped film cut to a required size corresponding to the workpiece W may be used.

The workpiece W preheated to a predetermined temperature by the preheating part 10 is held by the loader 4, and loaded into the opened mold frame 11a. In this case, when the workpiece W is pressed against a pair of X direction reference blocks 10c and Y direction reference blocks 10d on the preheating stage 10b with a pusher (not shown) or the like, the positional displacement in the direction of rotation is corrected by adjusting the orientation of the workpiece W. After workpiece alignment is performed, the amount of displacement between the workpiece center position and the stage center position is detected from the amount of positional displacement between the external form position of the workpiece W and the alignment mark. Each workpiece W has a dimensional tolerance of about ±1 mm, and when the workpiece W is preheated on the preheating stage 10b to a predetermined temperature, the workpiece W is elongated. Therefore, the workpiece holding position on the loader 4 may be corrected before the workpiece W is loaded into the mold frame 11a.

The multi-point chuck of the loader 4 is supported by providing a predetermined clearance with both ends of the workpiece in consideration of expansion and contraction of the workpiece W. The loader 4 is aligned with a lock block provided on the lower mold of the mold frame 11a, the workpiece W is delivered to the surface of the lower mold clamp, the workpiece W is sucked and held, the mold frame 11a is closed and the mold resin is heated and cured. Here, in the preheating stage 10b and the mold frame 11a, relief concave parts for avoiding interference with the chuck when the workpiece W is supported by the loader 4 are provided. In order to reduce the size of the relief concave part, it is preferable that the clearance between the chuck and both ends of the workpiece be as small as possible.

When the resin molding operation is completed, the mold frame 11a is opened, the loader 4 enters the frame, and the workpiece W is held and taken out. The workpiece W that is held by the loader 4 is conveyed to the cooling unit E by the press unit D, and delivered to a cooling stage 12 and cooled. The cooled workpiece W is subjected to a subsequent process (a dicing process, etc.). The movement range of the loader 4 in the X-Y direction is indicated by the dashed line shown in FIG. 1.

(Workpiece Transfer Part)

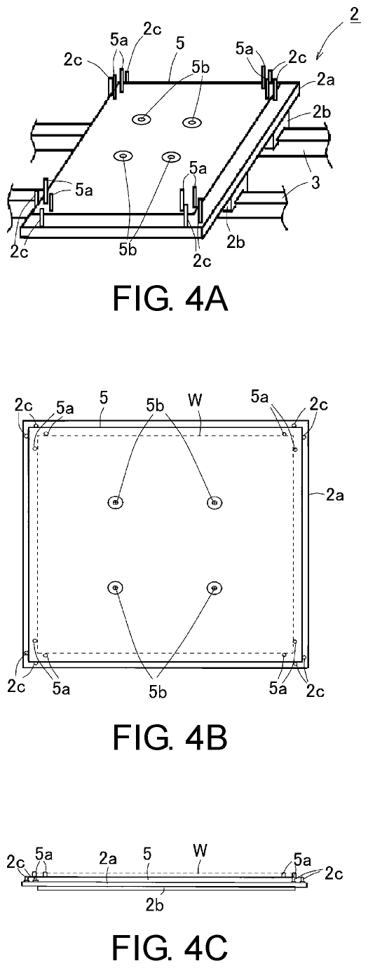

Here, a configuration of the workpiece transfer part 2 will be described with reference to FIG. 2 to FIG. 4. In FIG. 2, the transfer part main body 2a of the workpiece transfer part 2 is supported by the rail part 3 via a linear rail guide 2b. In FIG. 4A, on the upper surface of the transfer part main body 2a, a pair of guide pins 2c are erected and formed at four corners. The corners of the holder plate 5 formed in a rectangular shape are aligned and disposed between the guide pins 2c.

As shown in FIG. 4B, for the holder plate 5, a rectangular metal plate (for example, a stainless steel plate having high strength or a lightweight aluminum plate) having a size larger than the external form of the workpiece (about 500 mm to 600 mm) and a thick plate thickness (for example, about 10 mm) is used. Here, when the holder plate 5 is formed of a metal plate, according to cutting or grinding that enables precise processing, a large plate surface on which the workpiece W is disposed can be processed into a flat surface that is not distorted, and the workpiece W with high flatness can be supported and conveyed.

Thereby, even if the workpiece W has low rigidity, it does not deflect, and before it is loaded into the mold frame 11a, preheating to a predetermined temperature can be performed for each holder plate 5.

On the holder plate 5, a positioning member for positioning the workpiece W based on the external form is provided. As an example, in FIGS. 4B and 4C, on the holder plate 5, a pair of positioning pins 5a for positioning the workpiece W at four corners are provided. The workpiece W is disposed on the upper surface of the holder plate 5 by aligning corners of the workpiece W formed in a rectangular shape between the positioning pins 5a. The surface on which the workpiece is mounted and the positioning pins 5a of the holder plate 5 are preferably subjected to electro-static discharge (ESD) prevention coating (ESD coating) for preventing charging of static electricity in order to prevent electrostatic breakdown of the electronic component T on the workpiece W and prevent adhesion of a resin powder and dust.

In addition, as will be described below, the holder plate 5 is conveyed together with the workpiece W to the resin supply stage 7 of the resin supply unit B by the pick and place mechanism 8. In this case, on the resin supply stage 7, the electronic balance 7a is provided, and an amount of the resin supplied from the dispenser 6 is measured. Therefore, in the holder plate 5, preferably, holes are appropriately provided according to the measurement range of the electronic balance 7a, and the weight is reduced.

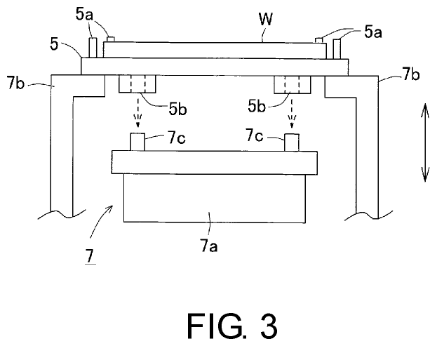

Next, in FIG. 2, when the workpiece transfer part 2 transfers the workpiece W and the holder plate 5 from the reception position P of the workpiece supply unit A to the position of the resin supply unit B, the holder plate 5 is held by the pick and place mechanism 8 and transferred to the resin supply stage 7. As shown in FIG. 3, the pick and place mechanism 8 delivers the workpiece W and the holder plate 5 to a lifter device 7b at an elevating position. The lifter device 7b descends while supporting the holder plate 5 and is disposed on the electronic balance 7a by fitting, for example, positioning pins 7c provided at four locations on the upper surface of the electronic balance 7a into, for example, positioning holes 5b (positioning parts: refer to FIGS. 4A and 4B) provided at four locations at the position corresponding to the holder plate 5. In this state, a granular resin or a liquid resin is supplied onto the workpiece W from the dispenser 6 shown in FIG. 2, measurement is performed with the electronic balance 7a at any time, and an appropriate amount of the resin is supplied.

Here, when the resin R such as a granular resin or a liquid resin is supplied onto the workpiece W, it is necessary to supply the mold resin to an appropriate position. For example, according to the granular resin, it is preferable to supply the mold resin to a position as close to the outer circumference as possible in the cavity in the mold frame 11a. In such a case, the holder plate 5 in the present invention positions the workpiece W with the positioning pin 5a and is positioned between the workpiece transfer part 2 and the resin supply stage 7 and then delivered, and therefore, at an appropriate position on the workpiece W, for example, while the centers are aligned, the mold resin can be supplied. The workpiece W to which the resin R is supplied and the holder plate 5 are elevated again by the lifter device 7b and held by the pick and place mechanism 8 at the elevating position, and delivered again to the workpiece transfer part 2. As shown in FIG. 1, the workpiece transfer part 2 transfers the workpiece W and the holder plate 5 to the delivery position Q of the workpiece delivery unit C.

In this manner, when the workpiece W and the holder plate 5 are transferred from the workpiece transfer part 2 to the resin supply stage 7 by the pick and place mechanism 8, the workpiece W is not bent, deformed, or damaged because the workpiece W that is supported by the holder plate 5 is transferred.

In addition, since the workpiece W is positioned based on the external form at a predetermined position on the holder plate 5, it is possible to prevent the resin from being supplied to a displaced position. In addition, when the positioning pins 7c of the electronic balance 7a are fitted into and overlap the positioning holes 5b of the holder plate 5, the workpiece W can be transferred onto the electronic balance 7a without positional displacement. In addition, since the workpiece W is not easily deformed, an appropriate amount of the resin can be supplied onto the workpiece W without uneven distribution.

As described above, when the workpiece W is received by the workpiece transfer part 2 in the previous process, since the workpiece W that is positioned with respect to and overlaps the holder plate 5 larger than the external form of the workpiece on the transfer part main body 2a is transferred, it is easy to handle until the thin and large-size workpiece W is delivered together with the resin to the loader 4, and the workpiece W and the resin can be supplied to the mold frame 11a while preventing the workpiece W from losing its flatness and being damaged.

While the workpiece W of the present example has been described using the rectangular carrier K, a circular carrier K such as a semiconductor wafer may be used. In this case, the holder plate 5 can be circular, and when the resin is supplied, the resin can be supplied from the dispenser 6 while rotating the holder plate 5.

In addition, in addition to being provided in the workpiece delivery unit C, the cleaner device 9 may be provided between the preheating stage 10b and the mold frame 11a in the press unit D.

In addition, the cleaner device 9 may be provided between the workpiece supply unit A and the resin supply unit B and between the resin supply unit B and the workpiece delivery unit C so that it not only cleans the back side (a surface on which no electronic component is mounted) of the workpiece W but also removes contaminants and dust suspended on the surface on which the electronic component is mounted.

As the mold frame 11a of the present example, the upper mold cavity type has been described, but a lower mold cavity type mold frame may be used. In this case, the workpiece W may be mounted on the holder plate 5 with a surface on which the electronic component is mounted downward, and may be transferred by the workpiece transfer part 2. In addition, a configuration in which the outer circumference of the holder plate 5 is clamped by the loader 4 and conveyed to the mold frame may be used.

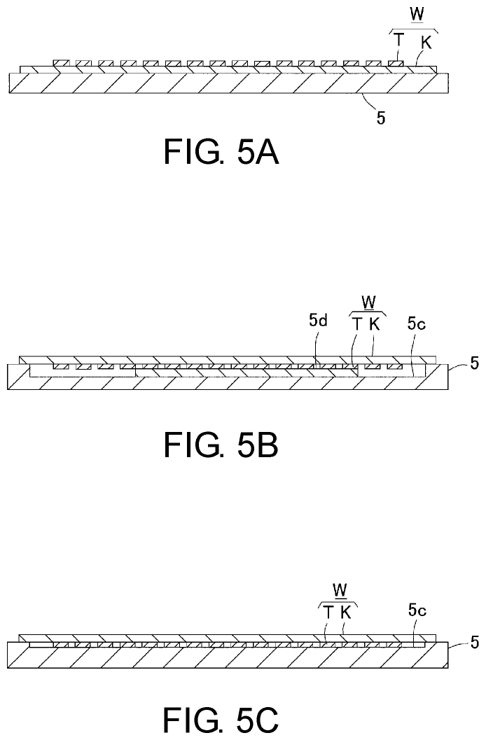

FIG. 5A shows a configuration of the upper mold cavity type holder plate 5 that supports a surface of the workpiece W on which no electronic component is mounted as described above. FIG. 5B and FIG. 5C show a configuration example of the lower mold cavity type holder plate 5.

In the configuration common to FIG. 5B and FIG. 5C, a concave part 5c is provided on the surface of the holder plate 5 on which the workpiece is mounted to avoid interference with the electronic component T (semiconductor chip) and support the carrier K flatly. In addition, a positioning member for positioning the workpiece W based on the external form is provided also in these holder plates 5 (not shown). In FIG. 5B, the electronic component T provided at least in the central part of the carrier, which has a larger deflection than the workpiece W, is supported by a reinforcing plate 5d disposed in the concave part 5c.

Here, the reinforcing plate 5d may not be a separate member but may have a convex part with a thick plate thickness integrally formed on the bottom of the concave part 5c. In FIG. 5C, the depth of the concave part 5c is equal to the height of the electronic component T, and the concave part 5c supports the entire electronic component. In this case, the deflection of the workpiece W can be minimized and the flatness can be maintained. In such a configuration, the workpiece W is conveyed together with the holder plate 5 to the loader 4, and only the workpiece W is supplied to the upper mold. On the other hand, the mold resin (a granular resin or a liquid resin) may be directly supplied from the resin supply unit B into the lower mold cavity by the dispenser, or the mold resin R that is disposed on the release film F may be supplied.

With these configurations, the thin and large-size workpiece can be stably and flatly conveyed in a predetermined alignment state.

It will be apparent to those skilled in the art that various modifications and variations can be made to the disclosed embodiments without departing from the scope or spirit of the present invention. In view of the foregoing, it is intended that the present invention covers modifications and variations provided that they fall within the scope of the following claims and their equivalents.

What is claimed is:

1. A resin molding device, in which a workpiece in which an electronic component is mounted on a thin plate type carrier and a mold resin are loaded into a mold frame and compressed and molded, comprising
a workpiece transfer part that reciprocates between a first position and a second position and transfers the workpiece,
wherein, in the workpiece transfer part, a holder plate larger than an external form of the workpiece and having a thick plate thickness is mounted on a transfer part main body, and
wherein the workpiece that is positioned with respect to and overlaps the holder plate based on the external form is transferred.

2. The resin molding device according to claim 1, wherein, in order to process the workpiece in a processing part provided on the way when the workpiece is transferred between the first position and the second position in the workpiece transfer part, the workpiece that is mounted on the holder plate is transferred to the processing part for each holder plate.

3. The resin molding device according to claim 1, wherein, in the holder plate, a positioning part that is aligned and mounted in a measuring unit provided in a resin supply part is provided.

4. The resin molding device according to claim 1, wherein the workpiece transfer part reciprocates between a reception position at which the workpiece is received in the previous process and a delivery position at which the workpiece is delivered to a loader into which the workpiece is loaded in the mold frame.

5. The resin molding device according to claim 1, wherein a concave part is formed in the holder plate, the electronic component mounted on the workpiece is housed in the concave part, and the workpiece is supported in an overlapping manner.

6. The resin molding device according to claim 5, wherein the electronic component is supported in the concave part with an auxiliary plate provided at least in the central part of the concave part.

7. The resin molding device according to claim 6, wherein the depth of the concave part is equal to the height of the electronic component mounted on the workpiece, and the entire mounted electronic component is supported by the concave part.

8. The resin molding device according to claim 1, wherein the holder plate is a metal plate.
